(19) United States
(12) Patent Application Publication
(10) Pub. No.: US 2024/0208804 A1
(43) Pub. Date: Jun. 27, 2024

(54) MEMS SENSOR AND METHOD OF MANUFACTURING MEMS SENSOR

(71) Applicant: ROHM CO., LTD., Kyoto (JP)

(72) Inventors: Martin Wilfried HELLER, Kyoto (JP); Toma FUJITA, Kyoto (JP)

(73) Assignee: ROHM CO., LTD., Kyoto (JP)

(21) Appl. No.: 18/538,105

(22) Filed: Dec. 13, 2023

(30) Foreign Application Priority Data
Dec. 21, 2022 (JP) 2022-204811

(51) Int. Cl. B81B 7/00; B81C 1/00

(52) U.S. Cl. CPC B81B 7/0041; B81C 1/00293; B81B 2201/0235; B81B 2201/0242; B81C 2203/0118

(57) ABSTRACT

A MEMS sensor includes: a first substrate; and a second substrate bonded to the first substrate, wherein at least one space, in which at least one sensor element is arranged, is formed inside at least one bonding portion where the first substrate and the second substrate are bonded, wherein at least one communication path communicating the space with outside of the bonding portion is formed in the first substrate, wherein the communication path includes an inner opening opened toward inside of the bonding portion, an outer opening opened toward outside of the bonding portion, and a tubular portion connecting the inner opening and the outer opening, and wherein the outer opening is closed by a sealing layer sealing the outer opening.

### CROSS-REFERENCE TO RELATED APPLICATION

This application is based upon and claims the benefit of priority from Japanese Patent Application No. 2022-204811, filed on Dec. 21, 2022, the entire contents of which are incorporated herein by reference.

### TECHNICAL FIELD

The present disclosure relates to a MEMS sensor and a method of manufacturing a MEMS sensor.

### BACKGROUND

MEMS (Micro Electro Mechanical System) sensors manufactured by using a semiconductor microfabrication technique are known. For example, in the related art, there is known a MEMS sensor in which a device-side substrate and a lid-side substrate are bonded by a glass frit and in which electrodes of a sensor element provided on the device-side substrate are sealed.

### BRIEF DESCRIPTION OF DRAWINGS

The accompanying drawings, which are incorporated in and constitute a part of the specification, illustrate embodiments of the present disclosure.

FIG. 1 is a schematic plan view of a MEMS sensor according to an embodiment of the present disclosure.

FIG. 2 is a plan view of a first substrate assembly.

FIG. 3 is an enlarged view of section A of the first substrate assembly shown in FIG. 2.

FIG. 4 is a cross-sectional view of the MEMS sensor taken along line IV-IV in FIG. 1.

FIG. 5 is a cross-sectional view of the MEMS sensor taken along line V-V in FIG. 1.

FIG. 6 is a cross-sectional view of the MEMS sensor taken along line VI-VI in FIG. 3.

FIG. 7 is a cross-sectional view of the MEMS sensor taken along line VII-VII in FIG. 3.

FIG. 8 is a plan view of a first substrate in which a communication path trench is formed.

FIG. 9 is a cross-sectional view of the first substrate taken along line IX-IX in FIG. 8.

FIG. 10 is a plan view of the first substrate in which the communication path trench is thermally oxidized.

FIG. 11 is a cross-sectional view of the first substrate taken along line XI-XI in FIG. 10.

FIG. 12 is a cross-sectional view of the first substrate taken along line XII-XII in FIG. 10.

FIG. 13 is a schematic plan view of a first substrate assembly and a second substrate assembly.

FIG. 14 is a cross-sectional view of the first substrate assembly and the second substrate assembly taken along line XIV-XIV in FIG. 13.

FIG. 15 is a view illustrating a method of manufacturing a first substrate assembly.

FIG. 16 is a view illustrating the method of manufacturing the first substrate assembly.

FIG. 17 is a view illustrating the method of manufacturing the first substrate assembly.

FIG. 18 is a view illustrating a method of manufacturing a second substrate assembly.

FIG. 19 is a view illustrating a method of manufacturing a MEMS sensor.

FIG. 20 is a view illustrating the method of manufacturing the MEMS sensor.

FIG. 21 is a view illustrating the method of manufacturing the MEMS sensor.

FIG. 22 is a view showing a first modification of the MEMS sensor.

FIG. 23 is a view showing a second modification of the MEMS sensor.

FIG. 24 is a view showing a third modification of the MEMS sensor.

FIG. 25 is a view illustrating another method of manufacturing a MEMS sensor.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of the present disclosure will be described below with reference to the accompanying drawings.

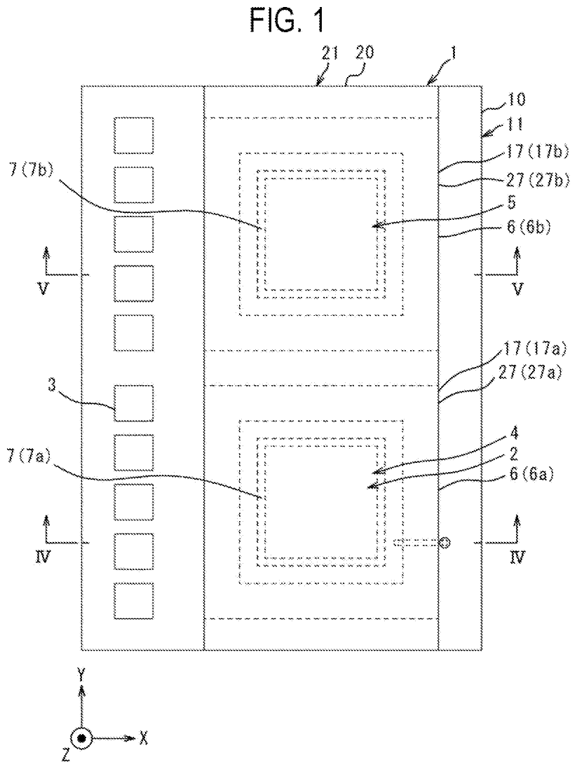

FIG. 1 is a schematic plan view of a MEMS sensor according to a first embodiment of the present disclosure. As shown in FIG. 1, the MEMS sensor 1 according to the first embodiment of the present disclosure is a MEMS combination sensor including a plurality of sensor elements as a sensor element 2. The MEMS sensor 1 includes a first substrate assembly 11 including a first substrate 10 as a device-side substrate having a sensor element 2, and a second substrate assembly 21 including a second substrate 20 as a lid-side substrate bonded to the first substrate 10 so as to cover the sensor element 2. The MEMS sensor 1 is manufactured by processing the first substrate 10 and the second substrate 20 using a semiconductor microfabrication technique.

Hereinafter, a predetermined direction extending along the surfaces of the first substrate 10 and the second substrate 20 will be referred to as an X direction, a direction perpendicular to the X direction will be referred to as a Y direction, and a thickness direction of the first substrate 10 and the second substrate 20 perpendicular to the X direction and the Y direction will be referred to as a Z direction. FIG. 1 shows the MEMS sensor 1 in which the second substrate 20 is bonded to the upper side of the first substrate 10 in the Z direction.

The sensor element 2 includes a gyro sensor element 4 as a first sensor element 4 and an acceleration sensor element 5 as a second sensor element 5. The sensor element 2 is arranged inside a bonding portion 6 where the first substrate 10 and the second substrate 20 are bonded. A space 7 in which the sensor element 2 is arranged is formed inside the bonding portion 6.

Although schematically shown, the gyro sensor element 4 is a well-known gyro sensor element configured to detect movement of a movable part 4a to detect an angular velocity thereof. The gyro sensor element 4 is arranged in a gyro sensor space 7a formed inside a gyro sensor bonding portion 6a where the first substrate 10 and the second substrate 20 are bonded.

Although schematically shown, the acceleration sensor element 5 is a well-known MEMS acceleration sensor element configured to detect movement of the movable part 5a to detect an acceleration thereof. The acceleration sensor element 5 is arranged in an acceleration sensor space 7b formed inside an acceleration sensor bonding portion 6b where the first substrate 10 and the second substrate 20 are bonded.

A plurality of pad portions 3 spaced apart from each other in the Y direction are provided on the first substrate 10. The pad portions 3 are connected to external electronic components and the like. The pad portions 3 are configured to input an electrical signal to the gyro sensor element 4 and output an electrical signal of the gyro sensor element 4, and is also configured to input an electrical signal to the acceleration sensor element 5 and output an electrical signal of the acceleration sensor element 5. A wiring electrically connected to the gyro sensor element 4, a wiring electrically connected to the acceleration sensor element 5, and a wiring electrically connected to the first substrate 10 are connected to the pad portions 3.

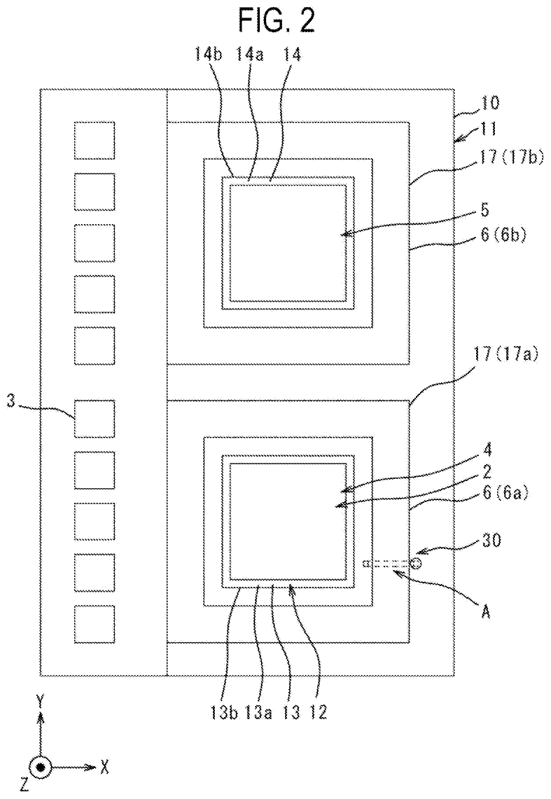

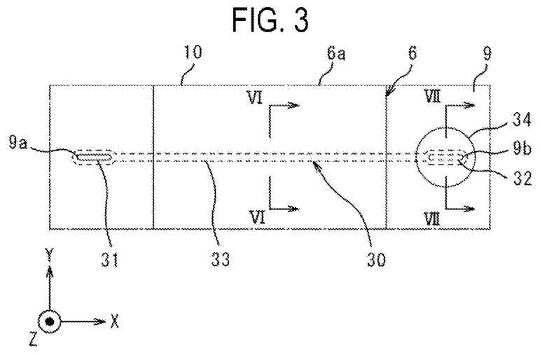

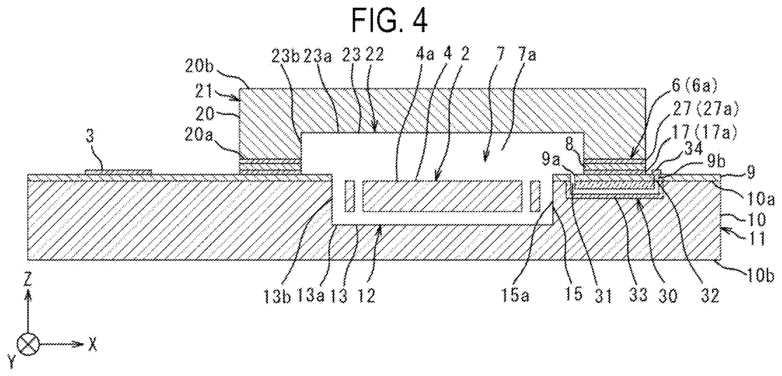

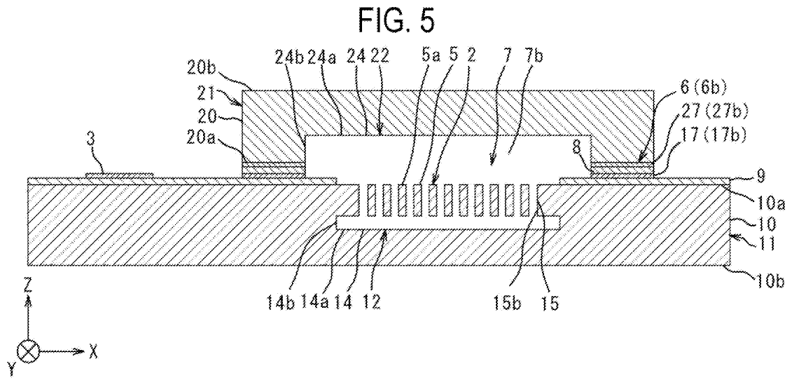

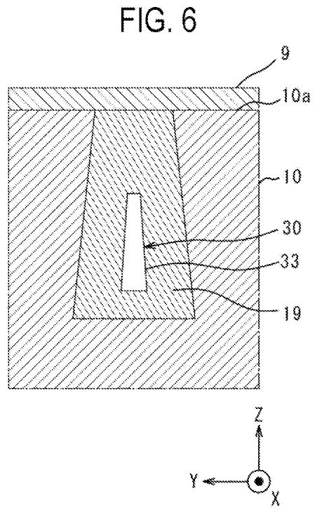

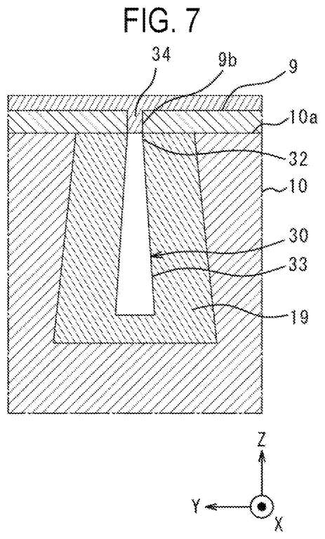

FIG. 2 is a plan view of a first substrate assembly. FIG. 3 is an enlarged view of section A of the first substrate assembly shown in FIG. 2. FIG. 4 is a cross-sectional view of the MEMS sensor taken along line IV-IV in FIG. 1. FIG. 5 is a cross-sectional view of the MEMS sensor taken along line V-V in FIG. 1. FIG. 6 is a cross-sectional view of the MEMS sensor taken along line VI-VI in FIG. 3. FIG. 7 is a cross-sectional view of the MEMS sensor taken along line VII-VII in FIG. 3.

As shown in FIGS. 4 and 5, the first substrate assembly 11 includes a first substrate 10 having a first main surface 10a, which is a front surface, and a second main surface 10b, which is a back surface opposite to the first main surface 10a. As shown in FIG. 2, the first substrate 10 is formed into a rectangular shape with two sides extending in the X direction and two sides extending in the Y direction, when viewed from above. As the first substrate 10, a monocrystalline silicon substrate is used.

The first substrate 10 includes a cavity 12 partially exposed on the first main surface 10a in a corresponding relationship with the sensor element 2. The cavity 12 includes a gyro sensor cavity 13 and an acceleration sensor cavity 14. As shown in FIG. 4, the gyro sensor cavity 13 is formed to be recessed in a substantially rectangular parallelepiped shape from the first main surface 10a in the thickness direction of the first substrate 10, and includes a bottom wall portion 13a and a side wall portion 13b extending from the bottom wall portion 13a in the thickness direction of the first substrate 10.

The first substrate 10 includes a support portion 15 that supports the movable part 4a of the gyro sensor element 4. The movable part 4a of the gyro sensor element 4 is arranged within the cavity 13 of the first substrate 10, and is supported by the support portion 15 while floating within the cavity 13. The movable part 4a of the gyro sensor element 4 is formed by a part of the first substrate 10. The support portion 15 includes a gyro sensor support portion 15a which is formed in a substantially rectangular annular shape in a plan view so as to surround the gyro sensor element 4. An inner peripheral surface of the gyro sensor support portion 15a constitutes the side wall portion 13b of the cavity 13.

As shown in FIG. 5, the acceleration sensor cavity 14 is formed to be recessed in a substantially rectangular parallelepiped shape from the first main surface 10a in the thickness direction of the first substrate 10, and includes a bottom wall portion 14a and a side wall portion 14b extending from the bottom wall portion 14a in the thickness direction of the first substrate 10.

The first substrate 10 includes a support portion 15 that supports the movable part 5a of the acceleration sensor element 5. The movable part 5a of the acceleration sensor element 5 is arranged within the cavity 14 of the first substrate 10, and is supported by the support portion 15 while floating within the cavity 14. The movable part 5a of the acceleration sensor element 5 is formed by a part of the first substrate 10. The support portion 15 includes an acceleration sensor support portion 15b which is formed in a substantially rectangular annular shape in a plan view so as to surround the acceleration sensor element 5. An inner peripheral surface of the acceleration sensor support portion 15b constitutes the side wall portion 14b of the cavity 14.

As shown in FIGS. 4 and 5, the second substrate assembly 21 includes a second substrate 20 having a first main surface 20a, which is a front surface, and a second main surface 20b, which is a back surface opposite to the first main surface 20a. As shown in FIG. 1, the second substrate 20 is formed in a rectangular shape with two sides extending in the X direction and two sides extending in the Y direction, in a plan view. The second substrate 20 is formed to be shorter than the first substrate 10 in the X direction. As the second substrate 20, a monocrystalline silicon substrate is used.

The second substrate 20 includes a cavity 22 recessed in a substantially rectangular parallelepiped shape from the first main surface 20a in the thickness direction of the second substrate 20. The cavity 22 includes a gyro sensor cavity 23 and an acceleration sensor cavity 24. As shown in FIG. 4, the gyro sensor cavity 23 has a bottom wall portion 23a and a side wall portion 23b extending in the thickness direction of the second substrate 20 from the bottom wall 23a. As shown in FIG. 5, the acceleration sensor cavity 24 has a bottom wall portion 24a and a side wall portion 24b extending in the thickness direction of the second substrate 20 from the bottom wall portion 24a.

The second substrate 20 is bonded to the first substrate 10 so as to cover the sensor element 2. The bonding portion 6 where the first substrate 10 and the second substrate 20 are bonded includes a gyro sensor bonding portion 6a and an acceleration sensor bonding portion 6b. A gyro sensor space 7a is formed inside the gyro sensor bonding portion 6a, and an acceleration sensor space 7b is formed inside the acceleration sensor bonding portion 6b. The space 7 is sealed by the bonding portion 6, and in the present embodiment, the pressure in the gyro sensor space 7a is set to be lower than that in the acceleration sensor space 7b.

The bonding portion 6 where the first substrate 10 and the second substrate 20 are bonded includes a first-substrate-side bonding portion 17 formed on the first substrate 10 and a second-substrate-side bonding portion 27 formed on the second substrate 20. The bonding portion 6 where the first substrate 10 and the second substrate 20 are bonded includes a glass frit 8 as a bonding material 8 that bonds the first-substrate-side bonding portion 17 and the second-substrate-side bonding portion 27, as shown in FIGS. 4 and 5. Other bonding materials may be used as the bonding material 8.

In the gyro sensor bonding portion 6a, the first-substrate-side bonding portion 17 includes a first-substrate-side gyro sensor bonding portion 17a and a first-substrate-side acceleration sensor bonding portion 17b. The second-substrate-side bonding portion 27 includes a second-substrate-side gyro sensor bonding portion 27a and a second-substrate-side acceleration sensor bonding portion 27b.

As shown in FIG. 2, the first-substrate-side bonding portion 17a is formed to surround the cavity 13, and is formed in a substantially rectangular annular frame shape in a plan view. As shown in FIG. 4, the first-substrate-side bonding portion 17a is made of an Al layer formed over the first main surface 10a of the first substrate 10 by a sputtering method or the like. In the present embodiment, the first-substrate-side bonding portion 17a is provided on a protective layer 9 formed on the first main surface 10a of the first substrate 10. As the protective layer 9, an Al layer formed by a sputtering method or the like is used. The pad portion 3 is provided on the protective layer 9 formed on the first main surface of the first substrate 10, and is made of an Al layer formed by a sputtering method or the like. The protective layer 9 may also be formed by laminating a highly airtight layer such as Al₂O₃ (alumina) on silicon oxide. In this case, the silicon oxide prevents oxygen and nitrogen, the highly airtight layer such as Al₂O₃ (alumina) prevents hydrogen and helium, and it is possible to maintain the pressure inside the cavity at a desired level even in a hydrogen or helium atmosphere.

As shown in FIG. 1, the second-substrate-side bonding portion 27a is formed in a substantially rectangular annular frame shape in a plan view, corresponding to the first-substrate-side bonding portion 17a. As shown in FIG. 4, the second-substrate-side bonding portion 27a is made of an Al layer formed on the first main surface 20a of the second substrate 20 by a sputtering method or the like. A glass frit 8 is provided on the second-substrate-side bonding portion 27a.

The second-substrate-side bonding portion 27a is bonded to the first-substrate-side bonding portion 17a via the glass frit 8. As a result, the gyro sensor space 7a formed inside the bonding portion 6 where the first substrate 10 and the second substrate 20 are bonded is sealed. Although not shown, the gyro sensor element 4 arranged in the gyro sensor space 7a is electrically isolated from the first substrate 10 by an isolation portion made of silicon oxide, and is connected to the pad portion 3 by a wiring that electrically connects the gyro sensor element 4 and the pad portion 3.

In the MEMS sensor 1, as shown in FIG. 3, a communication path 30 that communicates the space 7 with outside of the bonding portion 6 is formed in the first substrate 10, and includes an inner opening 31 opened toward inside of the bonding portion 6, an outer opening 32 opened toward outside of the bonding portion 6, and a tubular portion 33 that connects the inner opening 31 and the outer opening 32. The outer opening 32 is closed by a sealing layer 34 that seals the outer opening 32. Details of the communication path 30 will be described later.

The acceleration sensor bonding portion 6b is formed similarly to the gyro sensor bonding portion 6a. As shown in FIG. 2, the first-substrate-side bonding portion 17b is formed to surround the cavity 14, and is formed in a substantially rectangular annular frame shape in a plan view. As shown in FIG. 5, the first-substrate-side bonding portion 17b is made of an Al layer formed on the first main surface 10a of the first substrate 10 by a sputtering method or the like. In the present embodiment, the first-substrate-side bonding portion 17b is provided on the protective layer 9 formed on the first main surface 10a of the first substrate 10, and is made of an Al layer formed by a sputtering method or the like.

As shown in FIG. 1, the second-substrate-side bonding portion 27b is formed in a substantially rectangular annular frame shape in a plan view, corresponding to the first-substrate-side bonding portion 17b. As shown in FIG. 4, the second-substrate-side bonding portion 27b is made of an Al layer formed on the first main surface 20a of the second substrate 20 by a sputtering method or the like. A glass frit 8 is provided on the second-substrate-side bonding portion 27b.

The second-substrate-side bonding portion 27b is bonded to the first-substrate-side bonding portion 17b via the glass frit 8. As a result, the acceleration sensor space 7b formed inside the bonding portion 6 where the first substrate 10 and the second substrate 20 are bonded is sealed. Although not shown, the acceleration sensor element 5 arranged in the acceleration sensor space 7b is electrically isolated from the first substrate 10 by an isolation portion made of silicon oxide, and is connected to the pad portion 3 by a wiring that electrically connects the acceleration sensor element 5 and the pad portion 3.

As described above, in the MEMS sensor 1, the communication path 30 that communicates the space 7 with outside of the bonding portion 6 is formed in the first substrate 10, and includes the inner opening 31 opened toward inside of the bonding portion 6, the outer opening 32 opened toward outside of the bonding portion 6, and the tubular portion 33 that connects the inner opening 31 and the outer opening 32. The outer opening 32 is closed by the sealing layer 34 that seals the outer opening 32.

As for the space 7A in which the gyro sensor element 4 is arranged, as shown in FIGS. 3 and 4, the communication path 30 that communicates the space 7 with outside of the bonding portion 6 is formed in the first substrate 10. The communication path 30 is configured to communicate the gyro sensor space 7a with outside of the gyro sensor bonding portion 6a.

The communication path 30 includes the inner opening 31 opened toward the inside of the bonding portion 6a, the outer opening 32 opened toward outside of the bonding portion 6a, and the tubular portion 33 that connects the inner opening 31 and the outer opening 32. The inner opening 31 and the outer opening 32 are formed in the first main surface 10a of the first substrate 10, and the tubular portion 33 is formed inside the first substrate 10.

As shown in FIG. 3, each of the inner opening 31 and the outer opening 32 of the communication path 30 is formed in a slot shape which is longer in the X direction than in the Y direction when viewed from above, although the present disclosure is not limited thereto. The inner opening 31 and the outer opening 32 may have, for example, a square shape or a circular shape in a plan view. The tubular portion 33 of the communication path 30 is provided so as to extend linearly in the X direction in a plan view and communicate inside of the bonding portion 6 with outside of the bonding portion 6, although the present disclosure is not limited thereto. Although the tubular portion 33 is formed in a straight line shape in a plan view, it may be formed in other shapes such as a curved shape and the like.

As shown in FIG. 6, the tubular portion 33 of the communication path 30 is formed in a closed cross-sectional shape to have a substantially triangular cross-section, and has substantially the same cross-section in the X direction. As shown in FIG. 7, both ends of the tubular portion 33 are opened toward the first main surface 10a of the first substrate 10. The inner opening 31 and the outer opening 32 opened toward the first main surface 10a of the first substrate 10 are provided at both ends of the tubular portion 33. The communication path 30 is made of silicon oxide. The tubular portion 33 is formed of a silicon oxide film 19 which is an insulating film.

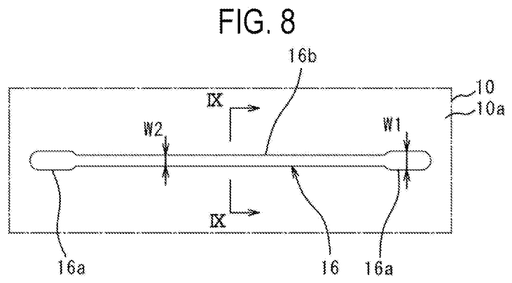

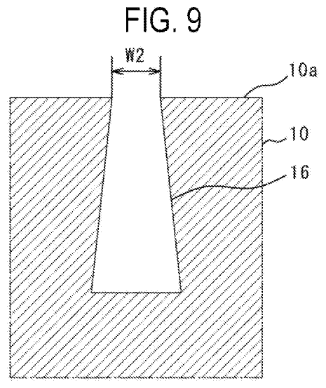

FIG. 8 is a plan view of the first substrate in which a communication path trench is formed. FIG. 9 is a cross-sectional view of the first substrate taken along line IX-IX in FIG. 8. As shown in FIGS. 8 and 9, the communication path 30 is formed of a silicon oxide film 19 as a thermal oxide film by removing a portion of the first substrate 10 corresponding to the communication path 30 by photolithography, etching, or the like to form a trench 16, and then thermally oxidizing the inner surface of the trench 16 by a thermal oxidation method. The communication path 30 May be formed of a silicon oxide film 19 formed on the inner surface of the trench 16 by a CVD method or the like.

The trench 16 is formed to taper toward the first main surface 10a side of the first substrate in a substantially triangular cross section so that the communication path 30 is formed by the silicon oxide film 19. As shown in FIG. 8, the trench 16 is formed so that a groove width W1 at both longitudinal end portions 16a is larger than a groove width W2 at the longitudinal center portion 16b and so that the groove width of both end portions of the communication path 30 corresponding to the inner opening 31 and the outer opening 32 is larger than that of the central portion between the both end portions. In the trench 16, for example, the groove width W1 is set to 2 μm, the groove width W2 is set to 1 μm, and the depth is set to 20 to 30 μm. The trench 16 may be formed to have a substantially rectangular cross section.

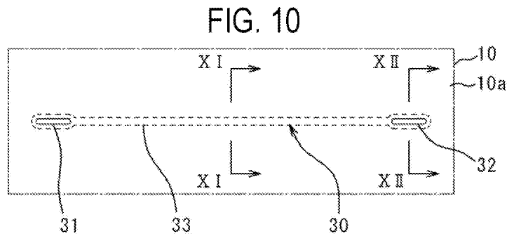

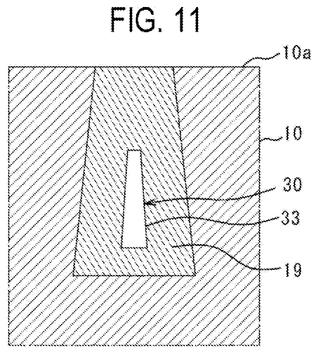

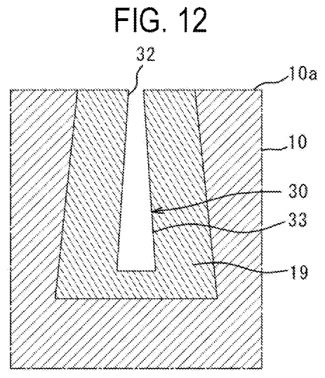

FIG. 10 is a plan view of the first substrate in which the communication path trench is thermally oxidized. FIG. 11 is a cross-sectional view of the first substrate taken along line XI-XI in FIG. 10. FIG. 12 is a cross-sectional view of the first substrate taken along line XII-XII in FIG. 10. As shown in FIGS. 10 to 12, when the trench 16 is thermally oxidized, a center portion in a longitudinal direction of the tubular portion 33 is formed in a shape of closed cross-section by the silicon oxide film 19, both ends in the longitudinal direction of the tubular portion 33 are opened by the silicon oxide film 19, and the inner opening 31 and the outer opening 32 are formed at both ends in the longitudinal direction of the tubular portion 33. The trench 16 is provided so that the communication path 30 is formed by thermal oxidation.

As shown in FIG. 4, a protective layer 9 for protecting the communication path 30 is formed on the first substrate 10 so as to cover the communication path 30. An inner through hole 9a and an outer through hole 9b that penetrate the protective layer 9 and correspond to the inner opening 31 and the outer opening 32 of the communication path 30 are formed in the protective layer 9. Each of the inner through hole 9a and the outer through hole 9b is formed in a slot shape to have substantially the same shape as the inner opening 31 and the outer opening 32 in a plan view, although the present disclosure is not limited thereto.

In this way, the communication path 30 is configured to communicate the gyro sensor space 7a with outside of the gyro sensor bonding portion 6a via the inner through hole 9a and the outer through hole 9b of the protective layer 9. In the MEMS sensor 1, in order to set the pressure in the gyro sensor space 7a at a predetermined pressure, a sealing layer 34 is formed on the first substrate 10 to seal the outer opening 32 in a predetermined pressure state, and the outer opening 32 is closed by the sealing layer 34.

As shown in FIGS. 3 and 4, the sealing layer 34 is formed in a substantially circular shape in a plan view, and is formed to fill the outer through hole 9b of the protective layer 9 and cover the outer opening 32. The sealing layer 34 is made of an Al layer 35 formed by a sputtering method or the like. As the sealing layer 34, a metal layer different from the Al layer may be used, or a sealing layer other than the metal layer may be used. Although the Al layer formed by a sputtering method or the like is used as the protective layer 9, it is also possible to use other protective layers such as a silicon oxide film and the like. The sealing layer 34 may also be formed by laminating a highly airtight layer such as Al₂O₃ (alumina) or the like on silicon oxide.

After the first substrate 10 and the second substrate 20 are bonded together under a first pressure such as an atmospheric pressure or the like, the sealing layer 34 for sealing the outer opening 32 is formed under a second pressure such as vacuum or the like, which is different from the first pressure, whereby the gyro sensor space 7a where the gyro sensor element 4 is arranged and the acceleration sensor space 7b where the acceleration sensor element 5 is arranged can be set to different predetermined pressures.

As described above, in the MEMS sensor 1, the space 7 in which the sensor element 2 is arranged is formed inside the bonding portion 6 between the first substrate 10 and the second substrate 20, and the communication path 30 that communicates the space 7 with outside of the bonding portion 6 is formed in the first substrate 10. The communication path 30 includes the inner opening 31 opened toward inside of the bonding portion 6, the outer opening 32 opened toward outside of the bonding portion 6, and the tubular portion 33 that connects the inner opening 31 and the outer opening 32. The outer opening 32 is closed by the sealing layer 34.

As a result, in the MEMS sensor 1, by closing the outer opening 32 with the sealing layer 34 in a state in which the pressure in the space 7 where the sensor element 2 is arranged is set to a predetermined pressure, it is possible to relatively easily set the pressure in the space 7 where the sensor element 2 is arranged to the predetermined pressure. Regarding the MEMS combination sensor as well, it is possible to relatively easily set the pressure in a plurality of spaces in which a plurality of sensor elements are respectively arranged to a predetermined pressure.

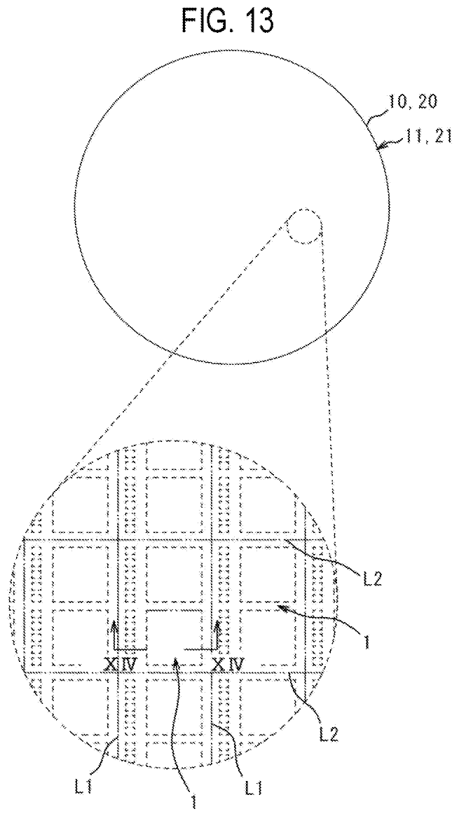

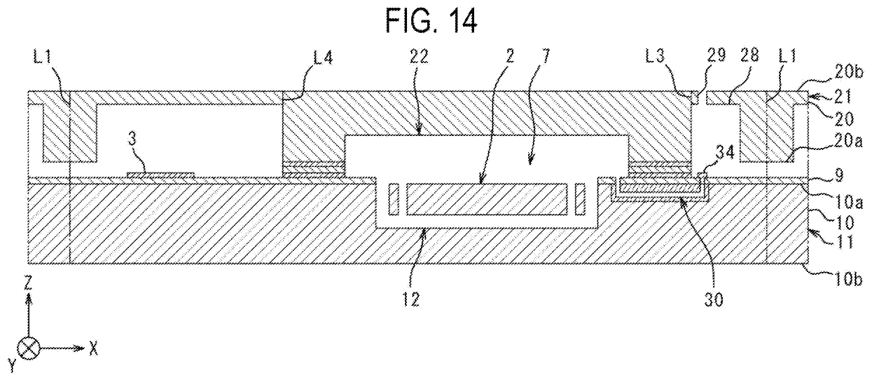

Next, a method of manufacturing the MEMS sensor 1 will be described. FIG. 13 is a schematic plan view of the first substrate assembly and the second substrate assembly. FIG. 14 is a cross-sectional view of the first substrate assembly and the second substrate assembly taken along line XIV-XIV in FIG. 13. Although the method of manufacturing the MEMS sensor 1 will be described below by using the cross sections of the first substrate assembly 11 and the second substrate assembly 21 in which the gyro sensor element 4 is arranged, except that the communication path 30 is formed, the portions of the first substrate assembly 11 and the second substrate assembly 21 where the acceleration sensor element 5 is arranged are also manufactured in the same manner.

As shown in FIG. 13, the MEMS sensor 1 is arranged in a matrix in a state in which the first substrate assembly 11 including the first substrate 10 and the second substrate assembly 21 including the second substrate 20 are superimposed and bonded. The MEMS sensor 1 is cut by dicing the same with a dicing blade along lines L1 and L2 set in a grid pattern.

Then, as shown in FIG. 14, the portion of the second substrate assembly 21 facing the sealing layer 34 and the portion of the second substrate assembly 21 facing the pad portion 3 are removed by dicing the same with a dicing blade along lines L3 and L4. Thus, the MEMS sensor 1 is manufactured.

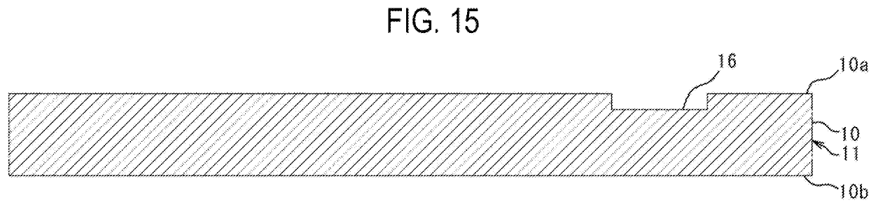

FIGS. 15 to 17 are views illustrating a method of manufacturing the first substrate assembly. FIGS. 15 to 17 are cross-sectional views corresponding to the cross-sectional views of the first substrate assembly 11 shown in FIGS. 4 and 14. In manufacturing the MEMS sensor 1, a first substrate 10 which is a silicon substrate and a second substrate 20 which is a silicon substrate bonded to the first substrate 10 so as to cover the sensor element 2 are prepared.

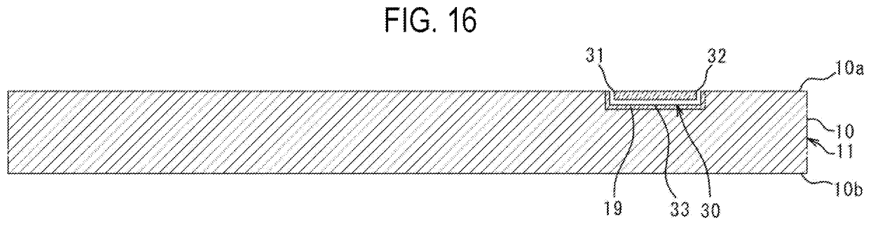

As shown in FIG. 15, a trench 16 corresponding to the communication path 30 is formed in the first substrate 10 by photolithography and etching. After forming the trench 16, as shown in FIG. 16, the inner surface of the trench 16 is thermally oxidized by a thermal oxidation method to form a silicon oxide film 19 as a thermal oxide film. A communication path 30 is formed on the first substrate 10 by the silicon oxide film 19. The communication path 30 has an inner opening 31, an outer opening 32, and a tubular portion 33.

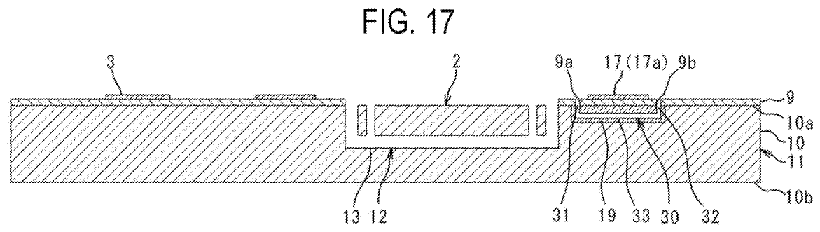

Next, as shown in FIG. 17, a protective layer 9 is formed on the first main surface 10a of the first substrate 10 by a sputtering method or the like, and an inner through hole 9a and an outer through hole 9b are formed in the protective layer 9 by photolithography and etching corresponding to the inner opening 31 and the outer opening 32 of the communication path 30. In the first substrate 10, an Al layer is also formed in the protective layer 9 by a sputtering method at the portions corresponding to the first-substrate-side bonding portion 17 and the pad portion 3, so that the first-substrate-side bonding portion 17 and the pad portion 3 are formed.

Thereafter, the first substrate 10 is patterned by photolithography and anisotropic etching. Then, by isotropic etching, a cavity 12 is formed to have a portion exposed on the first main surface 10a. A sensor element 2 is arranged inside the cavity 12 with the movable part thereof kept in a floating state. Thus, the first substrate assembly 11 is manufactured.

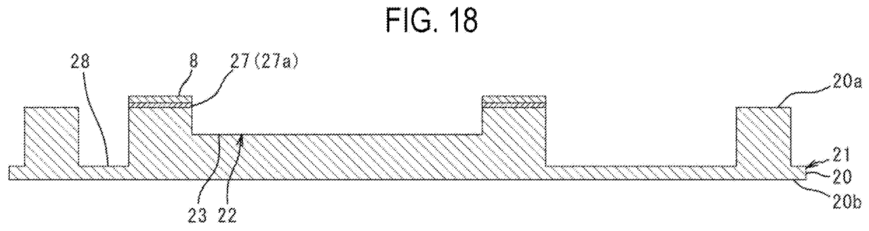

FIG. 18 is a view illustrating a method of manufacturing the second substrate assembly. FIG. 18 is a cross-sectional view corresponding to the cross-sectional views of the second substrate assembly 21 shown in FIGS. 4 and 14. As shown in FIG. 18, an Al layer is formed on the second substrate 20 by a sputtering method at the portion corresponding to the second-substrate-side bonding portion 27. Thus, the second-substrate-side bonding portion 27 is formed.

Then, by photolithography and etching, a cavity 22 is formed inside the second-substrate-side bonding portion 27 in the second substrate 20. A groove portion 28 recessed from the first main surface 20a is formed on the second substrate 20 outside the second-substrate-side bonding portion 27 so as to face the outer opening 32 of the communication path 30. The groove portion 28 is formed to have a substantially rectangular cross section and to extend linearly in the Y direction in a plan view, although the present disclosure is not limited thereto. Thereafter, a glass frit 8 is provided on the second-substrate-side bonding portion 27a. Thus, the second substrate assembly 21 is manufactured.

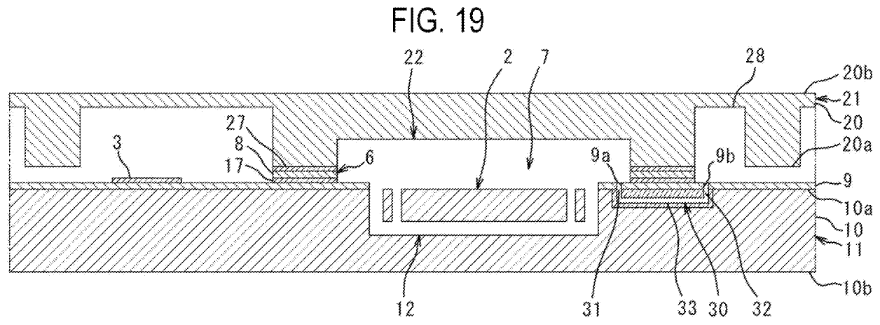

FIGS. 19 to 21 are views illustrating a method of manufacturing a MEMS sensor. After manufacturing the first substrate assembly 11 and the second substrate assembly 21, as shown in FIG. 19, the second substrate assembly 21 is bonded to the first substrate assembly 11, and the second substrate 20 is bonded to the first substrate 10 so as to cover the sensor element 2. The first-substrate-side bonding portion 17 and the second-substrate-side bonding portion 27 are bonded via the glass frit 8. The first-substrate-side bonding portion 17 and the second-substrate-side bonding portion 27 are bonded under the first pressure.

As described above, by bonding the second substrate 20 to the first substrate 10, a space 7 in which a sensor element 2 is arranged is formed inside the bonding portion 6 where the first substrate 10 and the second substrate 20 are bonded. A gyro sensor space 7a in which a gyro sensor element 4 is arranged is formed inside the gyro sensor bonding portion 6a, and an acceleration sensor space 7b in which an acceleration sensor element 5 is arranged is formed inside the acceleration sensor bonding portion 6b. The gyro sensor space 7a communicates with outside of the gyro sensor bonding portion 6a through the communication path 30, but the acceleration sensor space 7b is sealed under the first pressure.

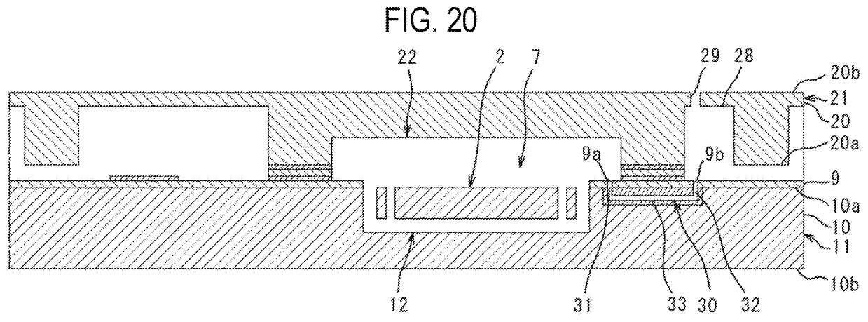

After the first substrate 10 and the second substrate 20 are bonded, as shown in FIG. 20, a communication hole 29 that communicates with the groove portion 28 from the second main surface 20b which is the back surface of the second substrate 20 is formed in the second substrate 20 by photolithography and etching. The communication hole 29 is provided at a position facing the outer opening 32 of the communication path 30, and is formed in a substantially circular shape in a plan view. The communication hole 29 may have other shapes such as a slot shape, a rectangular shape, and the like in a plan view so that the sealing layer 34 covers the outer opening 32.

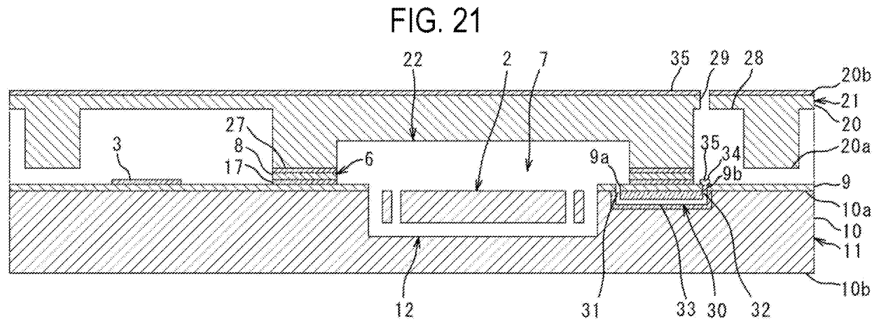

After the communication hole 29 is formed, as shown in FIG. 21, an Al layer 35 is formed on the second main surface 20b, which is the back surface of the second substrate 20, by a sputtering method or the like under the second pressure lower than the first pressure. In the portion of the second substrate 20 corresponding to the communication hole 29, the Al layer 35 is formed from the back surface of the second substrate 20 through the communication hole 29 to fill the outer through hole 9b of the protective layer 9 and cover the outer opening 32. As a result, the sealing layer 34 is formed in the outer opening 32 so that the outer opening 32 is closed by the sealing layer 34. The gyro sensor space 7a is sealed under the second pressure. The second pressure may be equal to or higher than the first pressure.

After forming the sealing layer 34, as shown in FIG. 14, the Al layer 35 formed on the second main surface 20b of the second substrate 20 is removed by etching. Thereafter, the second substrate assembly 21 is cut by dicing the same along lines L1, L2, L3, and L4. Thus, the MEMS sensor 1 is manufactured. The MEMS sensor 1 may be manufactured by cutting the second substrate assembly 21 by dicing without removing the Al layer 35 formed on the second main surface 20b of the second substrate 20.

As described above, in the method of manufacturing the MEMS sensor 1 according to the present embodiment, the second substrate 20 is bonded to the first substrate 10 so that the space 7 in which the sensor element 2 is arranged is formed inside the bonding portion 6 where the first substrate 10 and the second substrate 20 are bonded. The communication path 30, which includes the inner opening 31 opened toward inside of the bonding portion 6, the outer opening 32 opened toward outside of the bonding portion 6, and the tubular portion 33 for connecting the inner opening 31 and the outer opening 32, and which communicates the space 7 with outside of the bonding portion 6 is formed in the first substrate 10. The sealing layer 34 that seals the outer opening 32 is formed in the outer opening 32. Thus, the outer opening 32 is closed by the sealing layer 34.

As a result, in the MEMS sensor 1, by closing the outer opening 32 with the sealing layer 34 in a state in which the space 7 where the sensor element 2 is arranged is set to a predetermined pressure, the space 7 where the sensor element 2 is arranged can be set to the predetermined pressure in a relatively easy manner. Regarding the MEMS combination sensor as well, it is possible to relatively easily set a plurality of spaces in which a plurality of sensor elements are respectively arranged to predetermined pressures.

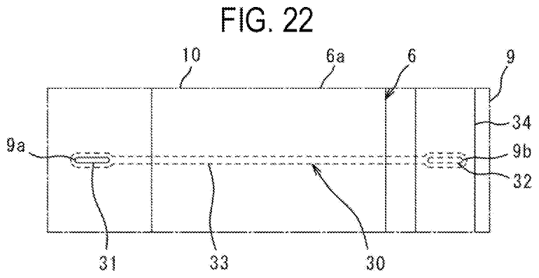

FIG. 22 is a view showing a first modification of the MEMS sensor. As shown in FIG. 22, in the MEMS sensor 1, the sealing layer 34 that closes the outer opening 32 May be formed in a linear shape extending in the Y direction in a plan view. In this case, the communication hole 29 is formed in a linear shape extending in the Y direction in a plan view, and may be formed by cutting the second substrate 20 by dicing the same.

In this way, by cutting the back surface of the second substrate 20 to form the communication hole 29 in the second substrate 20, the communication hole 29 can be formed using a normal wafer processing process such as dicing or the like, and the communication hole 29 can be formed relatively easier than in a case where the communication hole 29 is formed using a laser processing process.

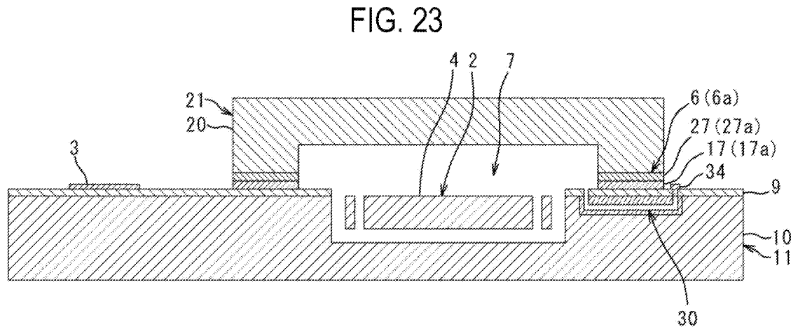

FIG. 23 is a view showing a second modification of the MEMS sensor. As shown in FIG. 23, in the MEMS sensor 1, the first-substrate-side bonding portion 17 and the second-substrate-side bonding portion 27 may be bonded without using a bonding material. The first-substrate-side bonding portion 17 may be made of an Al layer, the second-substrate-side bonding portion 27 may be made of a Ge layer, and the first-substrate-side bonding portion 17 and the second-substrate-side bonding portion 27 may bonded by metal bonding, specifically by eutectic bonding. The first-substrate-side bonding portion 17 and the second-substrate-side bonding portion 27 may be bonded by other metal bonding, and may be bonded by a bonding method different from the bonding using the bonding material 8 or the metal bonding.

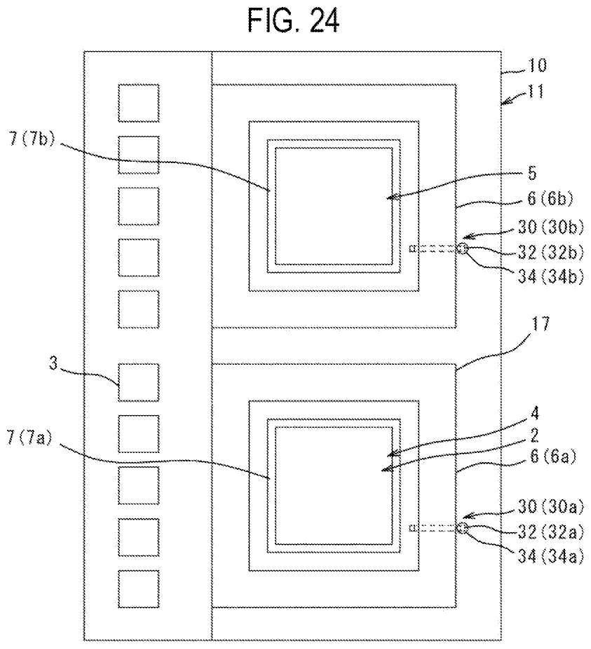

FIG. 24 is a view showing a third modification of the MEMS sensor. As shown in FIG. 24, in the MEMS sensor 1, the communication path 30 may also be formed in the space 7b where the acceleration sensor element 5 is arranged. In the MEMS sensor 1, a gyro sensor communication path 30a and an acceleration sensor communication path 30b may be formed. The acceleration sensor communication path 30b may be formed in the same manner as the gyro sensor communication path 30a.

In this case, after forming a gyro sensor communication hole, the outer opening 32a of the gyro sensor communication path 30a is closed by a sealing layer 34a under a first pressure. Then, after forming an acceleration sensor communication hole, the outer opening 32b of the acceleration sensor communication path 30b is closed by a sealing layer 34b under a second pressure equal to or different from the first pressure. Therefore, the gyro sensor space 7a and the acceleration sensor space 7b can be kept at predetermined pressures, respectively.

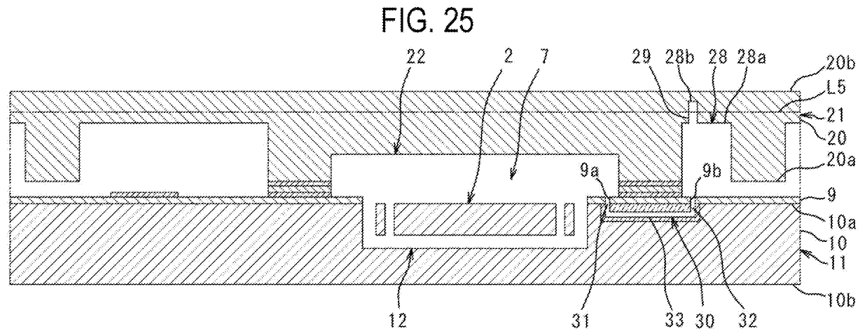

FIG. 25 is a view illustrating another method of manufacturing a MEMS sensor. As shown in FIG. 25, when manufacturing the second substrate assembly 21, regarding the groove portion 28 recessed from the first main surface 20a of the second substrate 20 so as to face the outer opening 32 of the communication path 30 outside the second-substrate-side bonding portion 27, a first groove portion 28a recessed from the first main surface 20a may be formed, a second groove portion 28b further recessed from the first groove 28a to form a communication hole 29 may be formed, and the communication hole 29 may be formed by back-grinding the second main surface 20b, which is the back surface of the second substrate 20, to the line L5.

Although the MEMS sensor 1 includes two sensor elements as the sensor element 2, it may include one sensor element or three or more sensor elements. In the case of including a plurality of sensor elements as the sensor element, a plurality of spaces 7 in which a plurality of sensor elements are respectively arranged are formed inside a plurality of bonding portions 6 where the first substrate 10 and the second substrate 20 are bonded, and at least one communication path 30 which brings at least one space 7 into communication with outside of the bonding portion 6 is formed in the first substrate 10.

In the present embodiment, the first sensor element is the gyro sensor element 4, and the second sensor element is the acceleration sensor element 5. However, the first sensor element and the second sensor element may be an infrared image sensor and an acceleration sensor element, or may be a pressure sensor element and an acceleration sensor element. In this way, various sensor elements can be used.

As described above, in the MEMS sensor 1 according to the present embodiment, the space 7 in which the sensor element 2 is arranged is formed inside the bonding portion 6 between the first substrate 10 and the second substrate 20, and the communication path 30 which brings the space 7 into communication with outside of the bonding portion 6 is formed in the first substrate 10. The communication path 30 includes the inner opening 31 opened toward inside of the bonding portion 6, the outer opening 32 opened toward outside of the bonding portion 6, and the tubular portion 33 that connects the inner opening 31 and the outer opening 32. The outer opening 32 is closed by the sealing layer 34.

As a result, in the MEMS sensor 1, by closing the outer opening 32 with the sealing layer 34 in a state in which the pressure in the space 7 where the sensor element 2 is arranged is set to a predetermined pressure, it is possible to relatively easily set the pressure in the space 7 where the sensor element 2 is arranged to the predetermined pressure. Regarding the MEMS combination sensor as well, it is possible to relatively easily set the pressures in a plurality of spaces in which a plurality of sensor elements are respectively arranged to predetermined pressures.

Furthermore, a plurality of spaces 7a and 7b in which a plurality of sensor elements 4 and 5 are arranged, respectively, are formed inside a plurality of bonding portions 6a and 6b where the first substrate 10 and the second substrate 20 are bonded. At least one communication path 30 that communicates at least one space 7a with outside of the bonding portion 6a is formed in the first substrate 10. Thus, regarding the MEMS combination sensor as well, it is possible to relatively easily set the pressures in a plurality of spaces in which a plurality of sensor elements are respectively arranged to predetermined pressures.

Further, the first substrate 10 is a silicon substrate, and the communication path 30 is formed of silicon oxide. As a result, by forming a trench 16 corresponding to the communication path 30 in the first substrate 10, which is a silicon substrate, and forming a silicon oxide film 19 such as a thermal oxide film or the like so as to fill the trench 16, it is possible to form the communication path 30 relatively easily.

Furthermore, a protective layer 9 is formed on the communication path 30 to protect the communication path 30. As a result, the protective layer 9 formed on the communication path 30 can improve the airtightness of the tubular portion 33 of the communication path 30, whereby the space 7 in which the sensor element 2 is arranged can be maintained at a predetermined pressure.

Further, the inner opening 31 and the outer opening 32 are formed on the surface 10a of the first substrate 10, and the tubular portion 33 is formed inside the first substrate 10. Thus, by forming a trench 16 corresponding to the communication path 30 on the surface 10a of the first substrate 10 and forming a silicon oxide film 19 such as a thermal oxide film or the like so as to fill the trench 16, it is possible to relatively easily form the communication path 30 including the inner opening 31, the outer opening 32, and the tubular portion 33.

Further, the sealing layer 34 is a metal layer 35. Thus, as compared with a case where the sealing layer 34 is formed of silicon oxide, the outer opening 32 can be closed with better airtightness by the metal layer 35, and the space 7 where the sensor element 2 is arranged can be relatively easily set to a predetermined pressure.

Further, in the method of manufacturing the MEMS sensor according to the present embodiment, the second substrate 20 is bonded to the first substrate 10, so that the space 7 in which the sensor element 2 is arranged is formed inside the bonding portion 6 where the first substrate 10 and the second substrate 20 are bonded. The communication path 30 including the inner opening 31 opened toward inside of the bonding portion 6, the outer opening 32 opened toward outside of the bonding portion 6, and the tubular portion 33 which connects the inner opening 31 and the outer opening 32, and configured to bring the space 7 into communication with outside of the bonding portion 6 is formed in the first substrate 10. The sealing layer 34 is formed in the outer opening 32, and the outer opening 32 is closed by the sealing layer 34.

As a result, in the MEMS sensor 1, by closing the outer opening 32 with the sealing layer 34 in a state in which the pressure in the space 7 where the sensor element 2 is arranged is set to a predetermined pressure, it is possible to relatively easily set the pressure in the space 7 where the sensor element 2 is arranged to the predetermined pressure. Regarding the MEMS combination sensor as well, it is possible to relatively easily set the pressures in a plurality of spaces in which a plurality of sensor elements are respectively arranged to predetermined pressures.

Furthermore, a plurality of spaces 7a and 7b in which a plurality of sensor elements 4 and 5 are arranged, respectively, are formed inside a plurality of bonding portions 6a and 6b where the first substrate 10 and the second substrate 20 are bonded. At least one communication path 30 that brings at least one space 7a into communication with outside of the bonding portion 6a is formed in the first substrate 10. Thus, as for the MEMS combination sensor as well, it is possible to relatively easily set the pressures in a plurality of spaces in which a plurality of sensor elements are respectively arranged to predetermined pressures.

Further, a groove portion 28 recessed from the surface 20a of the second substrate 20 is formed in the second substrate 20 so as to face the outer opening 32 outside the bonding portion 6, a communication hole 29 communicating with the groove 28 from the back surface 20b is formed in the second substrate 20, and a seal layer 34 is formed in the outer opening 32 from the back surface 20b of the second substrate 20 through the communication hole 29 to close the outer opening 32 with the sealing layer 34. As a result, by forming the groove portion 28 and the communication hole 29 through a normal wafer processing process such as an etching process or the like and forming the seal layer 34 under a predetermined pressure to close the outer opening 32, it is possible to relatively easily set the space in which the sensor element is arranged to a predetermined pressure.

Further, the back surface 29b of the second substrate 20 is cut to form the communication hole 29 in the second substrate 20. As a result, the communication hole 29 can be formed using a normal wafer processing process such as dicing or the like, and the communication hole 29 can be formed relatively easier than in a case where the communication hole is formed using a laser processing process.

Further, the back surface 20b of the second substrate 20 is ground to form a communication hole 29 in the second substrate 20. As a result, the communication hole 29 can be formed using a normal wafer processing process such as back grinding or the like, and the communication hole 29 can be formed relatively easier than in a case where the communication hole is formed using a laser processing process.

Furthermore, by forming the trench 16 corresponding to the communication path 30 in the first substrate 10 and forming the thermal oxide film 19 on the inner surface of the trench 16, the communication path 30 is formed in the first substrate 10. Thus, by forming the trench 16 and forming the thermal oxide film 19 on the first substrate 10, which is a silicon substrate, at the portion corresponding to the communication path 30, it is possible to relatively easily form the communication path 30.

Further, the trench 16 is formed so that both end portions 16a corresponding to the inner opening 31 and the outer opening 32 of the communication path 30 in a plan view have a groove width larger than that of the central portion 16b between both end portions 16a. As a result, by forming the trench 16 and forming the silicon oxide film 19 in the first substrate 10, which is a silicon substrate, at the portion corresponding to the communication path 30, it is possible to relatively easily form the communication path 30 including the inner opening 31, the outer opening 32, and the tubular portion 33.

The present disclosure is not limited to the illustrated embodiments, and various improvements and changes in design may be made without departing from the gist of the present disclosure.

### Supplementary Note 1

A MEMS sensor, comprising:
a first substrate; and
a second substrate bonded to the first substrate,
wherein at least one space, in which at least one sensor element is arranged is formed inside at least one bonding portion where the first substrate and the second substrate are bonded,
wherein at least one communication path communicating the space with outside of the bonding portion is formed in the first substrate,
wherein the communication path includes an inner opening opened toward inside of the bonding portion, an outer opening opened toward outside of the bonding portion, and a tubular portion connecting the inner opening and the outer opening, and
the outer opening is closed by a sealing layer sealing the outer opening.

### Supplementary Note 2

The MEMS sensor of Supplementary Note 1, wherein the at least one space includes a plurality of spaces, the at least one sensor element includes a plurality of sensor elements, and the at least one bonding portion includes a plurality of bonding portions,
wherein the plurality of spaces, in which the plurality of sensor elements are respectively arranged, are formed inside the plurality of bonding portions where the first substrate and the second substrate are bonded, and
wherein the at least one communication path communicating the at least one space with outside of the bonding portion is formed in the first substrate.

### Supplementary Note 3

The MEMS sensor of Supplementary Note 1 or 2, wherein the first substrate is a silicon substrate, and
wherein the communication path is formed of silicon oxide.

### Supplementary Note 4

The MEMS sensor of Supplementary Note 3, wherein a protective layer protecting the communication path is formed on the communication path.

### Supplementary Note 5

The MEMS sensor of any one of Supplementary Notes 1 to 4, wherein the inner opening and the outer opening are formed on a front surface of the first substrate, and
wherein the tubular portion is formed inside the first substrate.

### Supplementary Note 6

The MEMS sensor of any one of Supplementary Notes 1 to 5, wherein the sealing layer is a metal layer.

### Supplementary Note 7

A method of manufacturing a MEMS sensor, comprising:
preparing a first substrate;
preparing a second substrate bonded to the first substrate;
bonding the second substrate to the first substrate to form at least one space in which at least one sensor element is arranged, inside at least one bonding portion where the first substrate and the second substrate are bonded;
forming a communication path communicating the space with outside of the bonding portion in the first substrate, the communication path including an inner opening opened toward inside of the bonding portion, an outer opening opened toward outside of the bonding portion, and a tubular portion connecting the inner opening and the outer opening; and
forming a sealing layer sealing the outer opening in the outer opening to close the outer opening with the sealing layer.

### Supplementary Note 8

The method of Supplementary Note 7, wherein the at least one space includes a plurality of spaces, the at least one sensor element includes a plurality of sensor elements, and the at least one bonding portion includes a plurality of bonding portions,
wherein the plurality of spaces in which the plurality of sensor elements are respectively arranged are formed inside the plurality of bonding portions where the first substrate and the second substrate are bonded, and
wherein the at least one communication path communicating at least one of the spaces with outside of the bonding portion is formed in the first substrate.

### Supplementary Note 9

The method of Supplementary Note 7 or 8 comprising:
forming a groove portion recessed from a front surface of the second substrate so as to face the outer opening outside the bonding portion in the second substrate,
forming a communication hole communicating with the groove portion from a back surface of the second substrate in the second substrate, and
forming a sealing layer at the outer opening from the back surface of the second substrate through the communication hole to close the outer opening with the sealing layer.

### Supplementary Note 10

The method of Supplementary Note 9, whereinthe back surface of the second substrate is cut to form the communication hole in the second substrate.

### Supplementary Note 11

The method of Supplementary Note 9, whereinthe back surface of the second substrate is ground to form the communication hole in the second substrate.

### Supplementary Note 12

The method of any one of Supplementary Notes 7 to 11, wherein a trench corresponding to the communicating path is formed in the first substrate, and a thermal oxide film is formed on an inner surface of the trench to form the communicating path in the first substrate.

### Supplementary Note 13

The method of Supplementary Note 12, whereinthe trench is formed such that both end portions of the trench corresponding to the inner opening and the outer opening of the communication path have a larger groove width than a central portion between both end portions in a plane view.

The above description is merely an example. Those skilled in the art will appreciate that additional possible combinations and substitutions are possible beyond the components and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

1. A MEMS sensor, comprising:
a first substrate; and
a second substrate bonded to the first substrate,
wherein at least one space, in which at least one sensor element is arranged, is formed inside at least one bonding portion where the first substrate and the second substrate are bonded,
wherein at least one communication path communicating the space with outside of the bonding portion is formed in the first substrate,
wherein the communication path includes an inner opening opened toward inside of the bonding portion, an outer opening opened toward outside of the bonding portion, and a tubular portion connecting the inner opening and the outer opening, and
wherein the outer opening is closed by a sealing layer sealing the outer opening.

2. The MEMS sensor of claim 1, wherein the at least one space includes a plurality of spaces, the at least one sensor element includes a plurality of sensor elements, and the at least one bonding portion includes a plurality of bonding portions,
wherein the plurality of spaces, in which the plurality of sensor elements are respectively arranged, are formed inside the plurality of bonding portions where the first substrate and the second substrate are bonded, and
wherein the at least one communication path communicating the at least one space with outside of the bonding portion is formed in the first substrate.

3. The MEMS sensor of claim 1, wherein the first substrate is a silicon substrate, and wherein the communication path is formed of silicon oxide.

4. The MEMS sensor of claim 3, wherein a protective layer protecting the communication path is formed on the communication path.

5. The MEMS sensor of claim 1, wherein the inner opening and the outer opening are formed on a front surface of the first substrate, and
wherein the tubular portion is formed inside the first substrate.

6. The MEMS sensor of claim 1, wherein the sealing layer is a metal layer.

7. A method of manufacturing a MEMS sensor, comprising:
preparing a first substrate;
preparing a second substrate bonded to the first substrate;
bonding the second substrate to the first substrate to form at least one space, in which at least one sensor element is arranged, inside at least one bonding portion where the first substrate and the second substrate are bonded;
forming a communication path communicating the space with outside of the bonding portion in the first substrate, the communication path including an inner opening opened toward inside of the bonding portion, an outer opening opened toward outside of the bonding portion, and a tubular portion connecting the inner opening and the outer opening; and
forming a sealing layer sealing the outer opening in the outer opening to close the outer opening with the sealing layer.

8. The method of claim 7, wherein the at least one space includes a plurality of spaces, the at least one sensor element includes a plurality of sensor elements, and the at least one bonding portion includes a plurality of bonding portions,
wherein the plurality of spaces in which the plurality of sensor elements are respectively arranged are formed inside the plurality of bonding portions where the first substrate and the second substrate are bonded, and
wherein the at least one communication path communicating the at least one of the spaces with outside of the bonding portion is formed in the first substrate.

9. The method of claim 7, comprising:
forming a groove portion recessed from a front surface of the second substrate to face the outer opening outside the bonding portion in the second substrate,
forming a communication hole communicating with the groove portion from a back surface of the second substrate in the second substrate, and
forming a sealing layer at the outer opening from the back surface of the second substrate through the communication hole to close the outer opening with the sealing layer.

10. The method of claim 9, whereinthe back surface of the second substrate is cut to form the communication hole in the second substrate.

11. The method of claim 9, whereinthe back surface of the second substrate is ground to form the communication hole in the second substrate.

12. The method of claim 7, wherein a trench corresponding to the communicating path is formed in the first substrate, and a thermal oxide film is formed on an inner surface of the trench to form the communicating path in the first substrate.

13. The method of claim 12, whereinthe trench is formed such that both end portions of the trench corresponding to the inner opening and the outer opening of the communication path have a larger groove width than a central portion between the both end portions in a plan view.
